(19) United States
(12) Patent Application Publication
(10) Pub. No.: US 2026/0101761 A1
(43) Pub. Date: Apr. 9, 2026

(54) ASSEMBLY HAVING AT LEAST ONE PASSIVE COMPONENT

(71) Applicant: Siemens Aktiengesellschaft, 80333 München (DE)

(72) Inventors: STEFAN PFEFFERLEIN, Heroldsberg (DE); ALEXANDER HENSLER, Gerhardshofen (DE); JÖRG STROGIES, Berlin (DE)

(73) Assignee: Siemens Aktiengesellschaft, 80333 München (DE)

(21) Appl. No.: 19/112,192

(22) PCT Filed: Aug. 3, 2023
(86) PCT No.: PCT/EP2023/071571

§ 371 Date: Mar. 14, 2025

(30) Foreign Application Priority Data
Sep. 15, 2022 (EP) 22195903.4

(51) Int. Cl. H10W 44/00; G01R 15/14; G01R 19/00; H05K 1/181; H10D 80/20; H10W 40/25; H10W 70/63

(52) U.S. Cl. CPC H10W 44/401; G01R 15/146; G01R 19/0092; H05K 1/181; H10D 80/20; H10W 40/255; H10W 70/63

(57) ABSTRACT

An assembly includes a passive component embodied as a shunt resistor, and a first substrate including a first conductor track and a second conductor track, with the first conductor track being electrically conductively connected to the second conductor track by way of the passive component. The first substrate includes a cavity or an opening into which the passive component protrudes. A second substrate is electrically conductively connected to the first substrate by way of the passive component and includes a dielectric material layer. A heat sink is arranged on a side of the second substrate facing away from the first substrate and is connected to the passive component in an electrically insulating and thermally conductive manner by way of the dielectric material layer of the second substrate. The passive component is arranged on a side of the second substrate facing toward the first substrate.

The invention relates to an assembly having at least one passive component, a first substrate, a second substrate electrically conductively connected to the first substrate, and a heat sink.

The invention further relates to a power converter having at least one such semiconductor assembly.

Method for producing an assembly having at least one passive component, a first substrate, a second substrate electrically conductively connected to the first substrate, and a heat sink.

Such assemblies are used, for example, in a power converter. A power converter should be taken to mean, for example, a rectifier, an inverter, a converter or a DC-DC converter. Passive components, such as capacitors, snubbers as well as sensors, inter alia for determining currents, voltages, or temperatures, which are conventionally connected to a substrate may be used in a power converter. Such sensors may for example comprise a current-measuring resistor, a “shunt” resistor or a negative temperature coefficient thermistor (NTC), The passive components can be arranged, for example in order to achieve accurate measurement results, in a current-carrying path or in the region of a heat source, wherein sufficient heat dissipation must be ensured.

The patent application WO 2020/249479 A1 describes an electronic circuit with a first and a second circuit carrier and a first and a second semiconductor component. The first semiconductor component lies with its top against a bottom of the first circuit carrier and with its bottom against a top of the second circuit carrier. The first circuit carrier has a first throughplating which connects the first semiconductor component to a first conductor track. The first circuit carrier has a second throughplating which electrically connects a connection element arranged between the circuit carriers to a further conductor track.

Adequate heat dissipation is a challenge in particular in the case of such planar construction and connection methods. Against this background, it is an object of the present invention to enable improved heat dissipation for an assembly of the type mentioned in the introduction.

Said object is achieved according to the invention by an assembly having at least one passive component, a first substrate, a second substrate electrically conductively connected to the first substrate, and a heat sink, wherein the first substrate has a first conductor track and a second conductor track, wherein the first conductor track is electrically conductively connected to the second conductor track by way of the passive component, wherein the second substrate comprises a second dielectric material layer and wherein the passive component is connected to the heat sink in an electrically Insulating and thermally conductive manner by way of the second dielectric material layer of the second substrate, which heat sink is arranged on a side of the second substrate facing away from the first substrate, wherein the passive component, which takes the form of at least one shunt resistor, is arranged on a side of the second substrate facing toward the first substrate, wherein the first substrate has a cavity or an opening into which the passive component protrudes.

Said object is further achieved according to the invention by an assembly having at least one passive component, a first substrate, a second substrate electrically conductively connected to the first substrate, and a heat sink, wherein the first substrate has a first conductor track and a second conductor track, wherein the first conductor track is electrically conductively connected to the second conductor track by way of the passive component, wherein the second substrate comprises a second dielectric material layer and wherein the passive component is connected to the heat sink in an electrically insulating and thermally conductive manner by way of the second dielectric material layer of the second substrate, which heat sink is arranged on a side of the second substrate facing away from the first substrate, wherein the passive component, which takes the form of at least one shunt resistor, is arranged on a side of the first substrate facing toward the second substrate, wherein the passive component is arranged in a cavity of the first substrate.

The object is moreover achieved according to the invention by a power converter having at least one such assembly.

Said object is furthermore achieved according to the invention by a method for producing an assembly having at least one passive component, a first substrate, a second substrate electrically conductively connected to the first substrate, and a heat sink, wherein the first substrate has a first conductor track and a second conductor track, wherein an electrically conductive connection is produced between the first conductor track and the second conductor track by way of the passive component, wherein the second substrate comprises a second dielectric material layer and wherein the passive component is connected to the heat sink in an electrically insulating and thermally conductive manner by way of the second dielectric material layer of the second substrate, which heat sink is arranged on a side of the second substrate facing away from the first substrate, wherein the passive component, which takes the form of at least one shunt resistor, is arranged on a side of the second substrate facing toward the first substrate, wherein the first substrate has a cavity or an opening into which the passive component protrudes.

Said object is furthermore achieved according to the invention by a method for producing an assembly having at least one passive component, a first substrate, a second substrate electrically conductively connected to the first substrate, and a heat sink, wherein the first substrate has a first conductor track and a second conductor track, wherein an electrically conductive connection is produced between the first conductor track and the second conductor track by way of the passive component, wherein the second substrate comprises a second dielectric material layer and wherein the passive component is connected to the heat sink in an electrically insulating and thermally conductive manner by way of the second dielectric material layer of the second substrate, which heat sink is arranged on a side of the second substrate facing away from the first substrate, wherein the passive component, which takes the form of at least one shunt resistor, is arranged on a side of the first substrate facing toward the second substrate, wherein the passive component is arranged in a cavity of the first substrate.

The invention is based inter alia on the consideration of improving heat dissipation of an assembly having a passive component which electrically conductively connects a first conductor track to a second conductor track by connecting said component to a heat sink in electrically insulating and thermally conductive manner. The passive component may inter alia take the form of a sensor, in particular a current sensor, for example a shunt resistor, or temperature sensor, for example an NTC, but also a reactive component, for example a snubber. In particular if the passive component is arranged in a current-carrying path or in the region of a heat source, for example of a power transistor of a power converter, heat, in particular waste heat, arising during operation of the assembly is dissipated by way of the heat sink. The heat sink may inter alia take the form of a cooling member. The first and the second conductor tracks are arranged on a first substrate which may inter alia take the form of an, in particular multilayer, printed circuit board (PCB). The assembly furthermore comprises a second substrate electrically conductively connected to the first substrate, which second substrate comprises a dielectric material layer and may inter alia take the form of an, in particular two-layer, direct copper bonding (DCB) substrate. The passive component may be arranged on the first substrate or the second substrate in order to produce the electrically conductive connection between the first and the second conductor tracks. The heat sink is arranged on a side of the second substrate facing away from the first substrate. The second substrate electrically conductively connected to the first substrate is thus arranged between the first substrate and the heat sink, wherein the second substrate may lie flat on, and be connected to, the heat sink. The passive component is connected to the heat sink in an electrically insulating and thermally conductive manner by way of the second dielectric material layer. Heat arising during operation of the assembly is dissipated not only by way of the first and second conductor tracks, but also by way of the electrically insulating and thermally conductive connection to the heat sink. This additional heat path improves the assembly's heat dissipation.

The passive component is arranged on a side of the second substrate facing toward the first substrate. Such an assembly reduces the thermal resistance to the heat sink, so enhancing thermal contact, which, for example in the case of power converters of a higher power possibly exceeding 150 kW, In particular exceeding 750 kW, improves measurement accuracy and enables a long service life,

The first substrate has a cavity or an opening into which the passive component protrudes. A cavity or an opening reduces the distance between the first substrate, in particular PCB, and the second substrate, in particular DCB, so reducing the space requirement. Furthermore, in the event of a semiconductor element, for example a vertical power transistor, being coupled to the first substrate by way of a further DCB, the use of a common cooling member with a planar surface is enabled. Since passive components, such as shunt resistors, conventionally exceed the thickness of such a semiconductor element and this difference in height can be compensated by a cavity or an opening.

Alternatively, the passive component is arranged on a side of the first substrate facing toward the second substrate. Such an assembly enables low wiring resistance to the passive component and sufficient thermal contact to the heat sink.

The passive component is arranged in a cavity of the first substrate. A distance of the second substrate from the first substrate is adjustable by the depth of the cavity. In the event of a semiconductor element, for example a vertical power transistor, being coupled to the first substrate by way of a further DCB, the use of a common cooling member with a planar surface is enabled. Since passive components, such as shunt resistors, conventionally exceed the thickness of such a semiconductor element and this difference in height can be compensated by a cavity or an opening.

A further embodiment provides that the passive component takes the form of a sensor, wherein the assembly comprises at least one terminal for contacting the sensor. For example, the sensor takes the form of a shunt resistor which contains Zeranin, Manganin, Constantan, or Isaohm. The additional thermal coupling to the heat sink by way of the second substrate improves heat dissipation such that elevated measuring accuracy and a long service life are achievable.

A further embodiment provides that the passive component is arranged on a side of the first substrate facing away from the second substrate. Thermal coupling to the heat sink by way of the second substrate can be achieved, for example, by way of metallic throughplatings through the first substrate. Discrete standard SMD components are inter alia usable for the passive component. Such an assembly can be obtained simply and inexpensively.

A further embodiment provides that the passive component is electrically conductively connected to the first conductor track by way of a first contact and to the second conductor track by way of a second contact, wherein the passive component has an active part arranged between the first contact and the second contact, by way of which active part the passive component is thermally conductively connected to a first metallization of the second substrate. Such an assembly ensures very good thermal coupling of the passive component to the heat sink.

A further embodiment provides that the thermally conductive connection of the active part of the passive component to the first metallization of the second substrate is produced by a material bond. Such a material bond is producible inter alia by soldering, sintering or by a thermally conductive adhesive. Such a material bond ensures optimized thermal coupling of the passive component to the heat sink.

A further embodiment provides that the first conductor track and the second conductor track are in each case connected to the second substrate by way of at least one VIA, wherein the passive component includes an active part and wherein the VIAs are arranged to extend within a perpendicular projection surface of the active part of the passive component. A VIA (vertical interconnect access) can inter alia be an at least partial metallic throughplating which, for example, interconnects metallizations of different layers of a substrate. Such an assembly ensures a small distance between the VIAs. It may be necessary for reasons of insulation for the VIAs to be covered by the second substrate, A smaller distance between the VIAs ensures a more compact second substrate, which has a positive impact on costs for the assembly.

A further embodiment provides that the passive component has a substantially C-shaped cross-sectional contour, wherein contacts of the passive component which are connected to the first and second conductor tracks are arranged to point toward one another. In particular, thanks to such a C-shaped cross-sectional contour, contacts of the passive component connected to the first and second conductor tracks are embodied to point toward one another. The passive component has, for example, an interrupted circumferential profile, wherein contacts are arranged on an outer face of the interrupted circumferential profile and are connected to the respective conductor track in the region of the Interruption. This ensures a small distance between the VIAs of the respective conductor tracks.

A further embodiment provides that a first width of the second substrate is less than a second width of the passive component. The costs for the assembly are reduced by such a substrate.

A further embodiment provides that the passive component is potted, in particular completely. For example, a potting material, in which the passive component is embedded, is arranged between the first and second substrates.

A further embodiment provides at least one semiconductor element which is electrically conductively connected to the passive component, and a third substrate which is connected to the first substrate by way of the semiconductor element, wherein the semiconductor element and the third substrate are arranged on a side of the first substrate facing toward the second substrate, wherein the third substrate comprises a third dielectric material layer and wherein the semiconductor element is connected to the heat sink in an electrically insulating and thermally conductive manner by way of the third dielectric material layer of the third substrate. The semiconductor element may inter alia take the form of a vertical power transistor, in particular an insulated-gate bipolar transistor (IGBT). The second substrate and the third substrate are in particular connected to a common heat sink. The passive component which for example takes the form of at least one shunt resistor and the semiconductor element connected to the at least one shunt resistor may inter alia be part of a power converter. The shunt resistor and the semiconductor element can be effectively cooled by such an assembly such that it is possible to dispense with a separate shunt module even at higher power converter powers.

A further embodiment provides that the second substrate is thicker than the third substrate. Since in particular discrete shunt resistors conventionally distinctly exceed the thickness of the semiconductor element heightwise, height compensation can be achieved, in particular in the case of a small shunt thickness, by way of such a layer thickness adjustment of the respective dielectric material layers, so enabling the use of a common cooling member with a planar surface.

The invention is described and explained in greater detail below on the basis of the exemplary embodiments illustrated in the figures.

It is shown in:

FIG. 1 a schematic cross-sectional representation of a first embodiment of an assembly having a passive component,

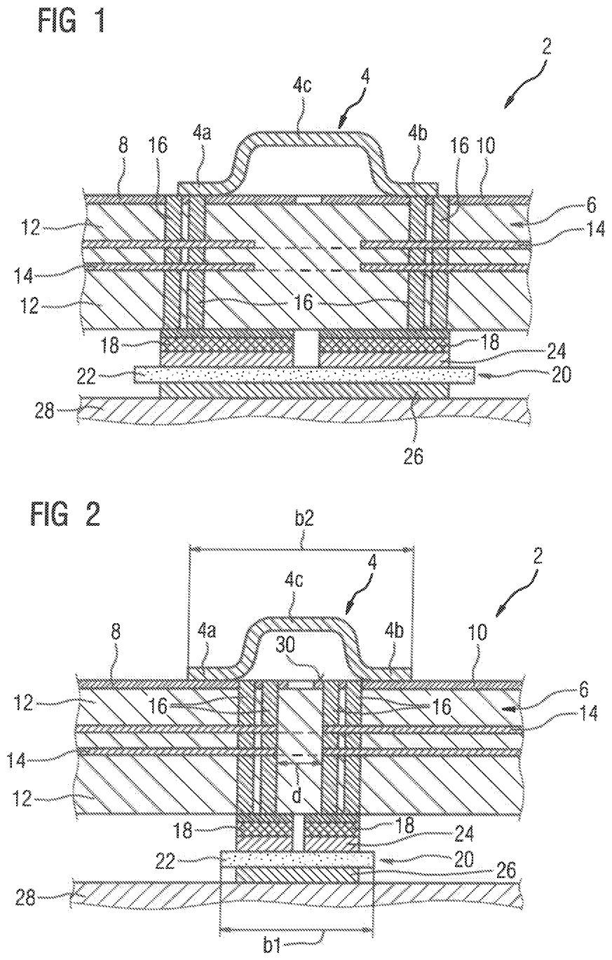

FIG. 2 a schematic cross-sectional representation of a second embodiment of an assembly having a passive component,

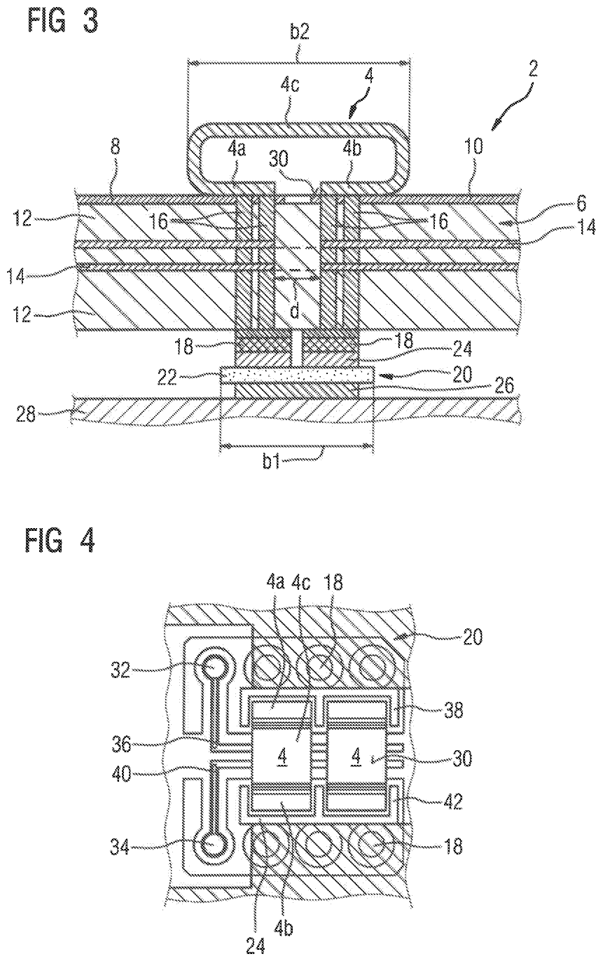

FIG. 3 a schematic cross-sectional representation of a third embodiment of an assembly having a passive component,

FIG. 4 a schematic representation, in plan view, of a fourth embodiment of an assembly having passive components,

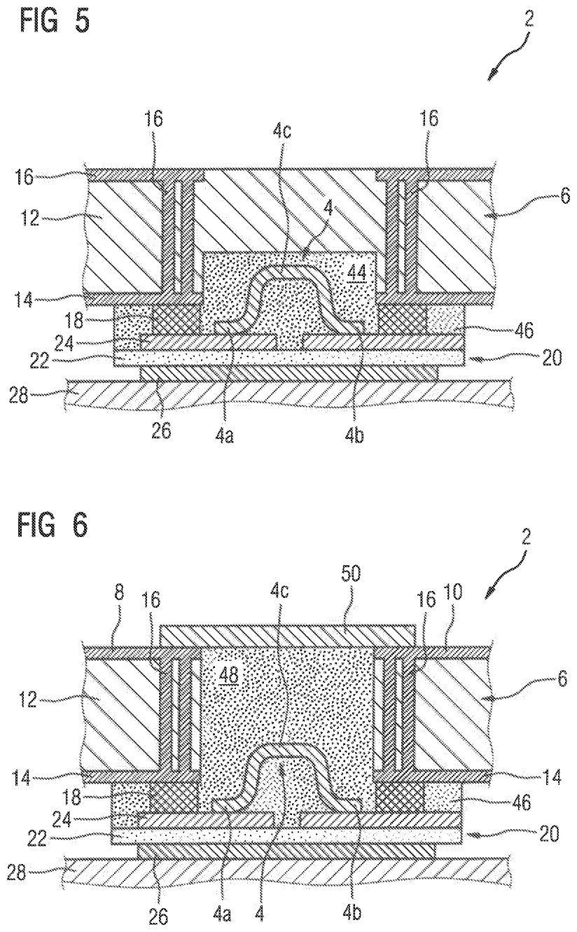

FIG. 5 a schematic cross-sectional representation of a fifth embodiment of an assembly having a passive component,

FIG. 6 a schematic cross-sectional representation of a sixth embodiment of an assembly having a passive component,

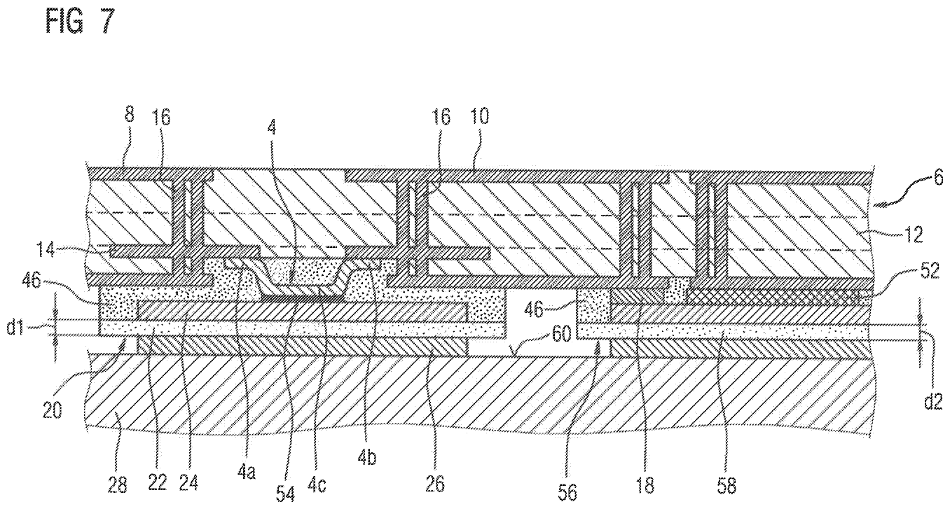

FIG. 7 a schematic cross-sectional representation of an assembly having a passive component and a semiconductor element,

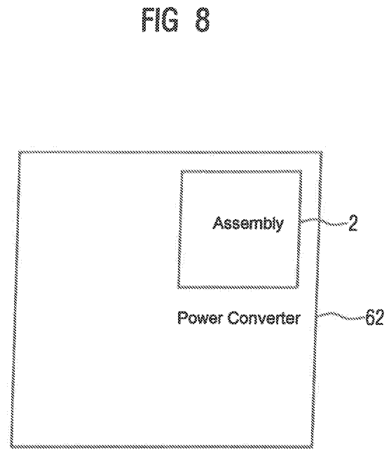

FIG. 8 a Schematic Representation of a Power Converter.

The exemplary embodiments set out below are preferred embodiments of the invention. In the exemplary embodiments, the described components of the embodiments are in each case individual features of the invention to be considered independently of one another, which in each case also mutually independently further develop the invention and are therefore to be considered part of the invention either individually or in a combination other than that indicated. The described embodiments can furthermore also be supplemented by further, previously described features of the invention.

The same reference signs have the same meaning in the various figures.

FIG. 1 shows a schematic cross-sectional representation of a first embodiment of an assembly 2 with a passive component 4 which is contacted on a first substrate 6. The first substrate 6, which takes the form of a PCB (printed circuit board), comprises a first conductor track 8 and a second conductor track 10, wherein the first conductor track 8 is electrically conductively connected by a material bond, in particular a soldered or sintered bond, to the second conductor track 10 by way of the passive component 4. The first substrate 6 further comprises by way of example three first dielectric material layers 12 which are produced for example from FR4. The first conductor track 8 and the second conductor track 10 in each case comprise parallel-connected metallizations 14, in particular copper metallizations, which are arranged on the first dielectric material layers 12, whereby a higher current-carrying capacity is achieved. The parallel connection is effected in each case by way of VIAs 16 (vertical interconnect access) which electrically conductively connect the metallizations 14. The conductor tracks 8, 10 of the first substrate 6 are furthermore connected by way of the VIAs 16 to spacer elements 18 which provide an electrically and thermally conductive connection to a second substrate 20. The spacer element 18, which is also known as a pad, is materially bonded, for example by a soldered or sintered bond, to the first substrate 6 and the second substrate 20. The first conductor track 8 and the second conductor track 10, to which the passive component 4 is bonded, are thus in each case connected by way of VIAs 16 to the second substrate 20.

The second substrate 20 takes the form of a DCB (direct copper bonding) substrate and comprises a second dielectric material layer 22 which is arranged between a first metallization 24 and a second metallization 26, wherein the first metallization 24 is connected to the second metallization 26 in an electrically insulating and thermally conductive manner by way of the second dielectric material layer 22. The second dielectric material layer 22 may contain inter alia a ceramic material, for example aluminum nitride or aluminum oxide, an organic material, for example a polyamide, or an organic material filled with a ceramic material. The first metallization 24 and the second metallization 26 are produced from copper or a copper alloy. A heat sink 28, which takes the form of a cooling member, is arranged on a side of the second substrate 20 facing away from the first substrate 6. The heat sink 28 is materially bonded, for example by a soldered or sintered bond, to the second metallization 26 of the second substrate 20, such that the passive component 4 is connected to the heat sink 28 in electrically insulating and thermally conductive manner by way of the second dielectric material layer 22 of the second substrate 20.

The passive component 4, which is arranged on a side of the first substrate 6 facing away from the second substrate 20, comprises a first contact 4a, by way of which the passive component 4 is electrically conductively connected to the first conductor track 8, and a second contact 4b, by way of which the passive component 4 is electrically conductively connected to the second conductor track 10. The passive component 4 furthermore has an active part 4c. By way of example, the passive component 4 takes the form of a sensor, in particular a current sensor, for example a shunt resistor, or temperature sensor, for example an NTC. At least the active part 4c of the sensor is made from an alloy which may contain inter alia Zeranin, Manganin, Constantan, Isaohm, or a PTC thermistor such as platinum.

FIG. 2 shows a schematic cross-sectional representation of a second embodiment of an assembly 2 with a passive component 4. The VIAs 16 which connect the conductor tracks 8, 10, to which the passive component 4 is connected, to the second substrate 20 are arranged to extend within a perpendicular projection surface 30 of the active part 4c of the passive component 4, so resulting in a smaller distance d between the VIAs 6 of the respective conductor tracks 8, 10 than in the configuration of FIG. 1. Since, for reasons of insulation, the VIAs 16 must be covered by the second substrate 20, the smaller distance d enables a more compact second substrate 20. In particular, a first width b1 of the second substrate 20 is smaller than a second width b2 of the passive component 4. The further embodiment of assembly 2 in FIG. 2 corresponds to that in FIG. 1.

FIG. 3 shows a schematic cross-sectional representation of a third embodiment of an assembly 2 with a passive component 4 which has a substantially C-shaped cross-sectional contour. The contacts 4a, 4b of the passive component 4 which are connected to the first and second conductor tracks 8, 10 are arranged to point toward one another. In particular, the passive component 4 takes the form of an interrupted circumferential profile, wherein the contacts 4a, 4b are arranged on an outer face and are connected to the respective conductor tracks 8, 10 in the region of the interruption. This enables a smaller distanced between the VIAs 6 of the respective conductor tracks 8, 10. In particular, a first width b1 of the second substrate 20 is smaller than a second width b2 of the passive component 4. The further embodiment of assembly 2 in FIG. 3 corresponds to that in FIG. 2.

FIG. 4 shows a schematic representation of a fourth embodiment of an assembly 2 with passive components 4 in plan view. The, by way of example two, passive components 4 take the form of shunt resistors and are arranged on a side of the second substrate 20 facing toward the first substrate 6. The assembly 2 further comprises terminals 32, 34 for contacting the shunt resistors. The first terminal 32 is connected by way of a first connecting lead 36 to a first sensor lead 38, while the second terminal 34 is connected by way of a second connecting lead 40 to a second sensor lead 42. The connecting leads 36, 38 are arranged to extend within a perpendicular projection surface 30 of the active parts 4c of the passive components 4. In order to save space, the connecting leads 36, 38 may optionally be guided one above the other in two different layers of the PCB. The sensor leads 38 are part of the first metallization 24 of the second substrate 20 and are connected by way of spacer elements 18 to the respective conductor tracks 8, 10 of the first substrate 6. The further embodiment of assembly 2 in FIG. 4 corresponds to that in FIG. 1.

FIG. 5 shows a schematic cross-sectional representation of a fifth embodiment of an assembly 2 with a passive component 4, wherein the passive component 4 is arranged on a side of the second substrate 20 facing toward the first substrate 6. The first substrate 6 has a cavity 44, into which the passive component 4 protrudes. The assembly comprises a potting material 46 which fills the cavity 44 and in which the passive component 4 is embedded. The further embodiment of assembly 2 in FIG. 5 corresponds to that in FIG. 4.

FIG. 6 shows a schematic cross-sectional representation of a sixth embodiment of an assembly 2 with a passive component 4, wherein the passive component 4 is arranged on a side of the second substrate 20 facing toward the first substrate 6. The first substrate 6 has an opening 48, into which the passive component 4 protrudes. The assembly comprises a potting material 46 which fills the opening 48 and in which the passive component 4 is embedded. A cover 50 closes the opening 48 on an opposing side of the first substrate 6 to the passive component 4. Prior to potting, the cover 50 is temporarily or permanently attached, in particular materially bonded, In sealing manner to the first substrate 6 and is optionally removable once the potting material 46 has cured. The further embodiment of assembly 2 in FIG. 6 corresponds to that in FIG. 5.

FIG. 7 shows a schematic cross-sectional representation of an assembly 2 with a passive component 4 and a semiconductor element 52. The passive component 4 is arranged on a side of the first substrate 6 facing toward the second 20. The passive component 4 is thermally conductively connected to the first metallization 24 of the second substrate 20 by way of the active part 4c arranged between the first contact 4a and the second contact 4b. The thermally conductive connection of the active part 4c of the passive component 4 to the first metallization 24 of the second substrate 20 is produced by a material bond 54, wherein the material bond 54 may be produced inter alia by soldering, sintering or by a thermally conductive adhesive. The passive component 4 is thermally coupled to the heat sink 28 by way of the material bond 54. Furthermore, no spacer elements 18 are required, so saving DCB area.

The semiconductor element 52 is electrically conductively connected to the passive component 4, By way of example, the semiconductor element 52 takes the form of a vertical power transistor, in particular an insulated-gate bipolar transistor (IGBT), In particular, the semiconductor element 52 is configured as a low-side switch of a half-bridge for a power converter which is connected on the collector side to an AC terminal by way of the passive component 4 configured as a shunt resistor.

The assembly 2 further comprises a third substrate 56 which is connected to the first substrate 6 by way of the semiconductor element 52 and a spacer element 18, wherein the semiconductor element 52 and the third substrate 56 are arranged on a side of the first substrate 6 facing toward the second substrate 20. The third substrate 20 comprises a third dielectric material layer 58, wherein the semiconductor element 52 is connected to a common heat sink 28 in electrically Insulating and thermally conductive manner by way of the third dielectric material layer 58 of the third substrate 56.

The common heat sink 28 has a planar surface 60. Since discrete shunt resistors conventionally distinctly exceed the thickness of the semiconductor heightwise, this difference in height is compensated by a cavity 44 on the PCB side. The passive component 4 in the form of a shunt resistor is arranged in the cavity 44 of the first substrate 6. The shunt resistor and the semiconductor element 52 are in each case embedded in potting material 46. Additionally or alternatively, height compensation can be achieved, in particular in the case of a small shunt thickness, by way of a layer thickness adjustment of the second dielectric material layer 22 or of the third dielectric material layer 58 in that a first thickness d1 of the second dielectric material layer 22 is selected to be smaller than a second thickness d2 of the third dielectric material layer 58.

FIG. 8 shows a schematic representation of a power converter 62 which, by way of example, comprises an assembly 2.

What is claimed is:

1.-15. (canceled)

16. An assembly, comprising:
a passive component embodied as a shunt resistor;
a first substrate including a first conductor track and a second conductor track, with the first conductor track being electrically conductively connected to the second conductor track by way of the passive component, said first substrate including a cavity or an opening into which the passive component protrudes;
a second substrate electrically conductively connected to the first substrate by way of the passive component and including a dielectric material layer; and
a heat sink arranged on a side of the second substrate facing away from the first substrate and connected to the passive component in an electrically insulating and thermally conductive manner by way of the dielectric material layer of the second substrate,
wherein the passive component is arranged on a side of the second substrate facing toward the first substrate.

17. The assembly of claim 16, wherein the passive component is formed as a sensor, the assembly further comprising a terminal designed to contact the sensor.

18. The assembly of claim 16, wherein the passive component is arranged on a side of the first substrate facing away from the second substrate.

19. The assembly of claim 16, wherein the first conductor track and the second conductor track are each connected to the second substrate via a VIA, said passive component including an active part, with the VIAs being arranged to extend within a perpendicular projection surface of the active part of the passive component.

20. The assembly of claim 16, wherein the passive component has a substantially C-shaped cross-sectional contour and includes contacts which are connected to the first and second conductor tracks and are arranged to point toward one another.

21. The assembly of claim 16, wherein the second substrate has a width which is smaller than a width of the passive component.

22. The assembly of claim 16, wherein the passive component is potted, in particular completely.

23. The assembly of claim 16, further comprising:
a semiconductor element electrically conductively connected to the passive component; and
a third substrate connected to the first substrate by way of the semiconductor element and comprising a dielectric material layer,
wherein the semiconductor element and the third substrate are arranged on a side of the first substrate facing toward the second substrate, and
wherein the semiconductor element is connected to the heat sink in electrically insulating and thermally conductive manner by way of the dielectric material layer of the third substrate.

24. The assembly of claim 23, wherein the second substrate has a thickness which is greater than a thickness of the third substrate.

25. An assembly, comprising:
a passive component embodied as a shunt resistor;
a first substrate including a first conductor track and a second conductor track, with the first conductor track being electrically conductively connected to the second conductor track by way of the passive component, said first substrate including a cavity in which the passive component is arranged;
a second substrate electrically conductively connected to the first substrate and including a dielectric material layer; and
a heat sink arranged on a side of the second substrate facing away from the first substrate and connected to the passive component in an electrically insulating and thermally conductive manner by way of the dielectric material layer of the second substrate,
wherein the passive component is arranged on a side of the first substrate facing toward the second substrate

26. The assembly of claim 25, wherein the passive component is electrically conductively connected to the first conductor track by way of a first contact and to the second conductor track by way of a second contact, said passive component including an active part arranged between the first contact and the second contact and designed to thermally conductively connect the passive component to a metallization of the second substrate.

27. The assembly of claim 26, wherein the active part of the passive component is thermally conductively connected to the metallization of the second substrate by a material bond.

28. The assembly of claim 25, wherein the first conductor track and the second conductor track are each connected to the second substrate by way of a VIA, said passive component including an active part, with the VIAs being arranged to extend within a perpendicular projection surface of the active part of the passive component.

29. The assembly of claim 25, wherein the passive component has a substantially C-shaped cross-sectional contour and includes contacts which are connected to the first and second conductor tracks and are arranged to point toward one another.

30. The assembly of claim 25, wherein the second substrate has a width which is smaller than a width of the passive component.

31. The assembly of claim 25, wherein the passive component is potted, In particular completely.

32. The assembly of claim 25, further comprising:
a semiconductor element electrically conductively connected to the passive component; and
a third substrate connected to the first substrate by way of the semiconductor element and comprising a dielectric material layer,
wherein the semiconductor element and the third substrate are arranged on a side of the first substrate facing toward the second substrate, and
wherein the semiconductor element is connected to the heat sink in electrically insulating and thermally conductive manner by way of the dielectric material layer of the third substrate.

33. The assembly of claim 32, wherein the second substrate has a thickness which is greater than a thickness of the third substrate.

34. A power converter, comprising the assembly of claim 16.

35. A power converter, comprising the assembly of claim 25.

36. A method for producing an assembly having a passive component, a first substrate, a second substrate electrically conductively connected to the first substrate, and a heat sink, the method comprising:
designing the passive component in a form of a shunt resistor;
arranging the passive component on a side of the second substrate facing toward the first substrate;
designing the passive component to protrude into a cavity or an opening of the first substrate;
electrically conductively connecting a first conductor track of the first substrate to a second conductor track of the first substrate by way of the passive component;
arranging the heat sink on a side of the second substrate facing away from the first substrate; and
connecting the passive component to the heat sink in an electrically insulating and thermally conductive manner by way of a dielectric material layer of the second substrate.

37. A method for producing an assembly having a passive component, a first substrate, a second substrate electrically conductively connected to the first substrate, and a heat sink, the method comprising:
designing the passive component in a form of a shunt resistor;
arranging the passive component on a side of the first substrate facing toward the second substrate in a cavity of the first substrate;
electrically conductively connecting a first conductor track of the first substrate to a second conductor track of the first substrate by way of the passive component;
arranging the heat sink on a side of the second substrate facing away from the first substrate; and
connecting the passive component to the heat sink in an electrically Insulating and thermally conductive manner by way of a dielectric material layer of the second substrate.
